(19) United States
(12) Patent Application Publication
(10) Pub. No.: US 2023/0284502 A1
(43) Pub. Date: Sep. 7, 2023

(54) DISPLAY APPARATUS

(71) Applicant: SAMSUNG DISPLAY CO., LTD., Yongin-si (KR)

(72) Inventors: Soodong KIM, Yongin-si (KR); Buyong KIM, Yongin-si (KR); Dahye PARK, Yongin-si (KR); Taeyoung SONG, Yongin-si (KR)

(21) Appl. No.: 18/106,408

(22) Filed: Feb. 6, 2023

(30) Foreign Application Priority Data
Mar. 7, 2022 (KR) 10-2022-0028933

(51) Int. Cl. H10K 59/38; H10K 59/80; C09K 11/02; C09K 11/62; C09D 11/50; C09D 11/322; C09D 11/38; C09D 11/037; C09D 11/107

(52) U.S. Cl. CPC H10K 59/38; H10K 59/873; C09K 11/025; C09K 11/621; C09D 11/50; C09D 11/322; C09D 11/38; C09D 11/037; C09D 11/107; H10K 59/12

(57) ABSTRACT

A display apparatus includes: a first substrate on which a light-emitting device is located; and a light controller on the first substrate and corresponding to the light-emitting device. The light controller includes: an organic capping layer; a quantum dot layer and/or a scattering layer; and a color filter layer. The organic capping layer is adjacent to the quantum dot layer and/or the scattering layer.

This application claims priority to Korean Patent Application No. 10-2022-0028933, filed on Mar. 7, 2022, and all the benefits accruing therefrom under 35 U.S.C. § 119, the content of which in its entirety is herein incorporated by reference.

### BACKGROUND

### 1. Field

One or more embodiments relate to a display apparatus.

### 2. Description of the Related Art

A display apparatus such as an organic light-emitting display apparatus produces an image by generating light based on the principle that holes and electrons injected from an anode and a cathode, respectively, recombine in an emission layer to emit light. For example, a desired color is expressed by a color combination of pixels that may each emit a color of light.

To this end, each pixel includes: a light-emitting device that may generate monochromatic light, such as white light or blue light; a quantum dot layer and a color filter for controlling the monochromatic light to be converted to a desired color of light, e.g., red light, green light, or blue light, for output. That is, when the light-emitting device of each pixel generates monochromatic light, the monochromatic light passes through the quantum dot layer and the color filter and is converted into one of red, green, and blue light, and then each color of light is emitted, thus realizing an image of a desired color by a color combination of the colors of light emitted from the pixels.

### SUMMARY

Provided is a display apparatus in which defects of a quantum dot layer due to permeation of oxygen or moisture is reduced.

Additional aspects will be set forth in part in the description which follows and, in part, will be apparent from the description, or may be learned by practice of the presented embodiments of the disclosure.

According to one or more embodiments, a display apparatus may include: a first substrate on which a light-emitting device may be located; and a light controller on the first substrate and corresponding to the light-emitting device, where the light controller may include an organic capping layer, a quantum dot layer and/or a scattering layer, and a color filter layer, and the organic capping layer is adjacent to the quantum dot layer or the scattering layer.

A monomer used in forming the organic capping layer and a monomer used in forming the quantum dot layer and/or the scattering layer may be the same type of monomer.

A monomer used in forming the organic capping layer may be an acrylic monomer.

A monomer used in forming the quantum dot layer and/or the scattering layer may be an acrylic monomer.

The light controller may include a quantum dot layer and a color filter layer, and the organic capping layer may be disposed between the quantum dot layer and/or the scattering layer, and the color filter layer.

The quantum dot layer and/or the scattering layer, and the organic capping layer may each be formed by an inkjet printer.

The quantum dot layer and/or the scattering layer, and the organic capping layer may each be cured simultaneously.

A monomer used in forming the organic capping layer may include hexamethylene diacrylate, tetraethylene glycol diacrylate, dipropylene glycol diacrylate, tripropylene glycol diacrylate, or any combination thereof.

A thickness of the organic capping layer may be in a range of about 0.1 micrometers (μm) to about 10 μm.

The light controller may further include a low-refractive-index layer, and the low-refractive-index layer may be disposed between the quantum dot layer and/or the scattering layer, and the color filter layer.

The quantum dot layer may include a quantum dot, and the quantum dot may include a group II-VI semiconductor compound; a group III-V semiconductor compound; a group III-VI semiconductor compound; a group semiconductor compound; a group IV-VI semiconductor compound; a group IV element or compound; or any combination thereof.

The group II-VI semiconductor compound may include CdS, CdSe, CdTe, ZnS, ZnSe, ZnTe, ZnO, HgS, HgSe, HgTe, MgSe, MgS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, CdZnSeS, CdZnSeTe, CdZnSTe, CdHgSeS, CdHgSeTe, CdHgSTe, HgZnSeS, HgZnSeTe, HgZnSTe, or any combination thereof.

The group III-V semiconductor compound may include GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or any combination thereof.

The group semiconductor compound may include GaS, GaSe, Ga₂Se₃, GaTe, InS, InSe, In₂S₃, In₂Se₃, InTe, InGaS₃, InGaSe₃, or any combination thereof.

The group semiconductor compound may include AgInS, AgInS₂, CuInS, CuInS₂, CuGaO₂, AgGaO₂, AgAlO₂, AgInGaS, or any combination thereof.

The group IV-VI semiconductor compound may include SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe, or any combination thereof.

The group IV element or compound may include Si, Ge, SiC, SiGe, or any combination thereof.

The display apparatus may further include a second substrate facing the first substrate,
where the light controller may be disposed between the first substrate and the second substrate, and
the organic capping layer may be disposed between the light-emitting device, and the quantum dot layer and/or scattering layer.

The display apparatus may further include an inorganic capping layer, and the inorganic capping layer may be disposed between the organic capping layer and the light-emitting device, and the inorganic capping layer may be adjacent to (e.g., in contact with) the organic capping layer.

The light-emitting device of the display apparatus may be configured to emit blue light, red light, or light consisting of a combination thereof.

The light-emitting device of the display apparatus may be configured to emit light including light of a wavelength in a range of about 380 nanometers (nm) to about 780 nm, and
the quantum dot layer may be configured to convert the blue light into one of red light and green light.

The color filter layer of the display apparatus may improve colorimetric purity of emitted light.

According to one or more embodiments, a light controller includes: a bank;
a quantum dot layer and/or a scattering layer in the bank;
an organic capping layer in the bank and adjacent to (e.g., in contact with) the quantum dot layer and/or the scattering layer; and
an inorganic capping layer covering the bank and the organic capping layer.

The light controller may further include a color filter layer.

Other aspects, features, and advantages other than those described above will become apparent from the following drawings, claims, and detailed description.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an embodiment of a display apparatus;

FIGS. 2A to 2E are schematic views sequentially illustrating a process of manufacturing the display apparatus of FIG. 1;

FIG. 3 is a schematic cross-sectional view of another embodiment of a display apparatus; and

FIG. 4 is a graph showing a comparison between peaks of a display apparatus according to one or more embodiments and a display apparatus in the related art.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the inventive concept allows for various changes and numerous embodiments, particular embodiments will be illustrated in the drawings and described in detail in the written description. Effects, features, and a method of achieving the inventive concept will be obvious by referring to example embodiments of the inventive concept with reference to the attached drawings. The inventive concept may, however, be embodied in many different forms and should not be construed as being limited to the embodiments set forth herein.

Hereinafter, the inventive concept will be described in detail by explaining example embodiments of the inventive concept with reference to the attached drawings. Like reference numerals in the drawings denote like elements, and thus their description will be omitted.

It will be understood that, although the terms “first”, “second”, etc. may be used herein to describe various elements, these elements should not be limited by these terms. These terms are only used to distinguish one element from another.

In the embodiments described in the present specification, an expression used in the singular encompasses the expression of the plural, unless it has a clearly different meaning in the context.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

In the present specification, it is to be understood that the terms such as “including,” “having,” and “comprising” are intended to indicate the existence of the features or components disclosed in the specification, and are not intended to preclude the possibility that one or more other features or components may exist or may be added.

Sizes of components in the drawings may be exaggerated for convenience of explanation. In other words, since sizes and thicknesses of components in the drawings are arbitrarily illustrated for convenience of explanation, the following embodiments are not limited thereto.

When a specific example may be implemented differently, a specific process order may be performed differently from the described order. For example, two processes described in succession may be performed substantially simultaneously or may be performed in an order opposite to the described order.

It will be understood that when a layer, region, or component is referred to as being “connected to” another layer, region, or component, the layer, region, or component may be directly connected to the another layer, region, or component, or indirectly connected to the another layer, region, or component as intervening layer, region, or component is present. For example, it will be understood that when a layer, region, or component is referred to as being “electrically connected to” another layer, region, or component, the layer, region, or component may be directly electrically connected to the another layer, region, or component, or indirectly electrically connected to the another layer, region, or component as intervening layer, region, or component is present.

According to one or more embodiments, a display apparatus may include:
a first substrate on which a light-emitting device may be located; and
a light controller on the first substrate and corresponding to the light-emitting device, where the light controller may include an organic capping layer, a quantum dot layer and/or a scattering layer, and a color filter layer, and
the organic capping layer may be adjacent to (e.g., in contact with) the quantum dot layer and/or the scattering layer.

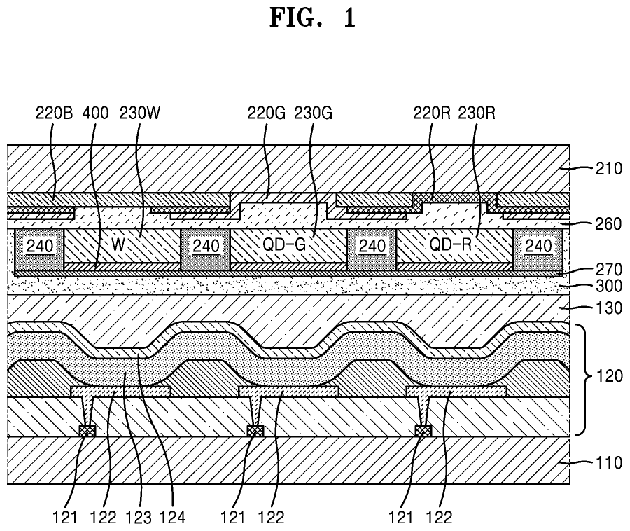

FIG. 1 is a schematic cross-sectional view of an embodiment of a display apparatus. In FIG. 1, the light-emitting device, the light controller, and the organic capping layer may each be plural. In addition, only one set of three-color pixels of red, green, and blue is shown in FIG. 1, however, in actual products, a plurality of sets of such three-color pixels may be distributed.

As shown in FIG. 1, the display apparatus according to an embodiment may include a structure including: a first substrate 110 on which a light-emitting device 120 may be located; a second substrate 210 on which quantum dot layers 230R and 230G, a scattering layer 230W, and color filter layers 220R, 220G, and 220B may be disposed as “light controllers”; and a filling material 300 interposed therebetween. In this embodiment, an organic capping layer 400 may be present between the light-emitting device 120 and the layers including the quantum dot layers 230R and 230G and/or the scattering layer 230W. An inorganic capping layer 270 may be present on the organic capping layer 400.

In another embodiment, although not shown in FIG. 1, the quantum dot layers 230R and 230G, the scattering layer 230W, and the color filter layer 220R, 220G, and 220B may be stacked directly on the light-emitting device 120 as light controllers. In this embodiment, after the light controllers are directly stacked on the light-emitting device 120 located on the first substrate 110, a display apparatus may be manufactured by bonding the first substrate 110 and the second substrate 210. In this embodiment, the organic capping layer 400 may be disposed between the quantum dot layers 230R and 230G and the color filter layers 220R and 220G, and the organic capping layer 400 may be disposed between the scattering layer 230W and the color filter layer 220B.

In still another embodiment, although not shown in FIG. 1, a display apparatus may be manufactured such that the quantum dot layers 230R and 230G, the scattering layer 230W, and the color filter layer 220R, 220G, and 220B may be stacked directly on the light-emitting device 120 disposed on the first substrate as light controllers, without a second substrate. In this embodiment, the organic capping layer 400 may be disposed between the quantum dot layers 230R and 230G and the color filter layers 220R and 220G, and the organic capping layer 400 may be disposed between the scattering layer 230W and the color filter layer 220B.

The light-emitting device 120 may have a structure in which an interlayer 123 including an emission layer may be disposed between the first electrode 122 and the second electrode 124, and holes and electrons injected from the two electrodes 122 and 124, respectively, may recombine in the emission layer in the interlayer 123, thus generate light. For example, red, green, and blue pixels may absorb, transmit, and/or generate light having a wavelength in a range of about 380 nanometers (nm) to about 780 nm. That is, for example, the light-emitting device 120 may generate light having a wavelength in a range of about 380 nm to about 500 nm, light having a wavelength of about 380 nm to about 650 nm, or light having a wavelength of about 380 nm to about 780 nm. The light controller of each pixel may convert the light into red, green, and blue. The light-emitting device 120 will be described in detail later.

A reference numeral 121 indicates a pixel circuit connected to the first electrode 122, and includes elements such as a thin-film transistor and a capacitor. Also, a reference numeral 130 indicates a thin-film encapsulation layer that protects the light-emitting device 120 by covering the same, and may be a single-layered film of an organic film or an inorganic film, or may be a multi-layered film in which an organic film and an inorganic film are alternately stacked. The inorganic film may include silicon oxide, silicon nitride, and/or silicon oxynitride, and the organic film may include polyethylene terephthalate, polyethylene naphthalate, polycarbonate, polyimide, polyethylene sulfonate, polyoxymethylene, polyarylate, hexamethyldisiloxane, acryl-based resin (for example, polymethylmethacrylate or polyacrylic acid), or any combination thereof.

The light controllers may include an organic capping layer, a quantum dot layer and/or a scattering layer, and a color filter layer.

The quantum dot layers 230R and 230G, the scattering layer 230W, and the color filter layers 220R, 220G, and 220B may be prepared as the light controllers. The quantum dot layer 230R may convert blue light generated from the light-emitting device 120 into red light, and the quantum dot layer 230G may convert blue light generated from the light-emitting device 120 into green light. The color filter layers 220R, 220G, and 220B may increase color purity by filtering out stray light that may be partially mixed in the converted color. Here, the quantum dot layer 230R and the color filter layer 220R both may be provided in the red pixel and the quantum dot layer 230G and the color filter layer 220G both may be provided in the green pixel, whereas the scattering layer 230W and the blue color filter layer 220B may be provided in the blue pixel. The reason is that the light generated by the light-emitting device 120 is, for example, blue light. That is, blue light is not required to convert the light in the blue pixel, and blue light may pass through the scattering layer 230W only. Thus, the blue color filter layer 220B for filtering the stray light is provided. The scattering layer 230W may include a scatterer.

A reference numeral 260 denotes a low-refractive-index layer having the refractive index of about 1.2. The side-scattered light that has passed through the quantum dot layers 230R and 230G and the scattering layer 230W, is totally reflected at the interface of the low-refractive-index layer 260 due to the difference between the refractive index of the quantum dot layers 230R and 230G and the scattering layer 230W and the refractive index of the low-refractive-index layer 260, so that the light is re-scattered inside the quantum dot layers 230R and 230G and the scattering layer 230W. The low-refractive-index layer 260 may increase luminance by converting side scattering to front scattering.

In some embodiments, the light controller may further include a low-refractive-index layer, and the low-refractive-index layer may be disposed between the quantum dot layer and/or the scattering layer, and the color filter layer.

In an embodiment, the organic capping layer 400 and the quantum dot layers 230R and 230G may be physically in direct contact with each other. In addition, the organic capping layer 400 and the scattering layer 230W may be in direct contact physically with each other.

In an embodiment, a monomer included in the organic capping layer 400 and a monomer included in the quantum dot layers 230R and 230G and/or the scattering layer 230W may be monomers of the same series.

The quantum dot layer 230R and 230G may be formed by a solution process, for example, an inkjet process using an ink composition for forming quantum dots. The ink composition may include a quantum dot, a monomer, an initiator, and an additive. The additive may include, for example, a dispersant, a viscosity modifier, or any combination thereof. The ink composition may not include a solvent. The initiator may be a common initiator used to cure polymers.

The initiator may include, for example, TPO, Quantacure BMS, oxime-base compound as follows, or ethyl phenyl(2,4,6-trimethylbenzoyl)phosphinate):

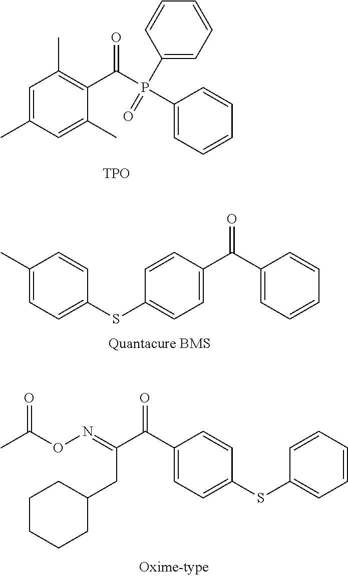

The initiator may be included in an amount of about 0.1 percent by weight (wt %) to about 50 wt % based on 100 wt % of the monomer.

The additive may be included in an amount of about 0.1 wt % to about 50 wt % based on 100 wt % of the monomer.

The scattering layer 230W may be formed by a solution process, for example, an inkjet process using an ink composition for forming a scattering layer. For example, the ink composition may be an equivalent ink composition except for using a scatterer instead of a quantum dot in the ink composition for forming quantum dots. The scatterer may include, for example, titanium, silver, aluminum, or an oxide of any combination thereof.

The organic capping layer 400 may be formed by a solution process, for example, an inkjet process using an ink composition for forming an organic capping layer. In an embodiment, the ink composition may include a monomer, an initiator, and an additive. The additive may include, for example, a dispersant, a viscosity modifier, or any combination thereof. The ink composition may not include a solvent. The monomer, initiator, and additive used in the ink composition for forming an organic capping layer may be understood by referring to the descriptions of the monomer, initiator, and additive used in the ink composition for forming quantum dots.

First, after forming the quantum dot layers 230R and 230G and/or the scattering layer 230W with inkjet, the organic capping layer 400 may be formed with inkjet on the quantum dot layer 230R and 230G and/or the scattering layer 230W.

The thus formed organic capping layer 400 may be crosslinked with the quantum dot layer 230R and 230G and/or the scattering layer 230W by heat or light simultaneously. In this process, when an ink composition for forming quantum dots or ink composition for forming a scattering layer and an ink composition for forming an organic capping layer is in contact with each other, an inorganic material (e.g., quantum dots or a scatterer) may be diffused. However, as a viscosity of the ink composition for forming quantum dots or the ink composition for forming a scattering layer may be greater than a viscosity of the ink composition for forming an organic capping layer, such a diffusion may be reduced.

To reduce the diffusion, the ink composition for forming an organic capping layer may not be too different from the ink composition for forming quantum dots and/or the ink composition for forming a scattering layer. For example, the ink composition for forming an organic capping layer may be an ink composition from which an inorganic material (e.g., quantum dots) is removed from the ink composition for forming quantum dots or the ink composition for forming a scattering layer.

In an embodiment, for example, a monomer used in forming or included in the organic capping layer and a monomer used in forming or included in the quantum dot layer and/or the scattering layer may be monomers of the same series. For example, when a monomer used in forming or included in the organic capping layer is hydrophobic, a monomer used in forming or included in the quantum dot layer and/or the scattering layer may also be hydrophobic. For example, when a monomer used in forming or included in the organic capping layer is hydrophilic, a monomer used in forming or included in the quantum dot layer and/or the scattering layer may also be hydrophilic.

In an embodiment, for example, when the dispersant included in the ink composition for forming quantum dots or the ink composition for forming a scattering layer contains an amine moiety or an acid moiety, the dispersant included in the ink composition for forming an organic capping layer may also be an amine moiety or an acid moiety. For example, when the dispersant included in the ink composition for forming quantum dots or the ink composition for forming a scattering layer contains an amine moiety, and the dispersant included in the ink composition for forming an organic capping layer contains an amine moiety, precipitation may not occur. For example, when the dispersant included in the ink composition for forming quantum dots or the ink composition for forming a scattering layer contains an acid moiety, and the dispersant included in the ink composition for forming an organic capping layer contains an acid moiety, precipitation may not occur.

In an embodiment, for example, when the dispersant included in the ink composition for forming quantum dots or the ink composition for forming a scattering layer contains an amphiphilic moiety (with an amine moiety and an acid moiety), the dispersant included in the ink composition for forming an organic capping layer may also be an amphiphilic moiety.

In an embodiment, for example, when the dispersant included in the ink composition for forming quantum dots or the ink composition for forming a scattering layer contains an amine moiety or an acid moiety, and the dispersant included in the ink composition for forming an organic capping layer contains an amphiphilic moiety, precipitation may occur. Therefore, in this case, for example, the organic capping layer 400; and the quantum dot layer 230R and 230G or the scattering layer 230W may not be formed at the same time by crosslinking.

In an embodiment, a monomer used in forming or included in the organic capping layer may be an acrylic monomer.

In some embodiments, a monomer used in forming or included in the quantum dot layer and/or the scattering layer may be an acrylic monomer.

In some embodiments, a monomer used in forming or included in the organic capping layer may include hexamethylene diacrylate, tetraethylene glycol diacrylate, dipropylene glycol diacrylate, tripropylene glycol diacrylate, or any combination thereof.

In some embodiments, a monomer used in forming or included in the quantum dot layer and/or the scatterer layer may include hexamethylene diacrylate, tetraethylene glycol diacrylate, dipropylene glycol diacrylate, tripropylene glycol diacrylate, or any combination thereof.

In some embodiments, a thickness of the organic capping layer may be in a range of about 0.1 micrometers (μm) to about 10 μm. In some embodiments, a thickness of the organic capping layer may be in a range of about 0.5 μm to about 5.0 μm. when the thickness of the organic capping layer is less than 0.1 μm, the organic capping layer may not sufficiently cover the quantum dot layer, and when the thickness is greater than 10 μm, curing efficiency of the organic capping layer; and the quantum dot layer and/or the scatterer layer simultaneously may be poor.

In an embodiment, a vapor pressure of the ink composition for forming an organic capping layer may be in a range of about 10⁻⁶ mmHg to about 10⁻³ mmHg.

In an embodiment, a surface energy of the ink composition for forming an organic capping layer may be in a range of about 1 dyne/cm to about 20 dyne/cm.

In an embodiment, a viscosity of the ink composition for forming an organic capping layer may be in a range of about 1 cps to about 40 cps.

When the vapor pressure, the surface energy, and the viscosity of the ink composition for forming an organic capping layer is within these ranges, the ink composition for forming an organic capping layer may be suitable for a solution process, e.g., an inkjet process.

A reference numeral 240 in FIG. 1 denotes a bank that demarcates between the light controllers (e.g., a scatterer layer or a quantum dot layer) of each pixel.

A portion formed by overlapping the color filter layers 220R, 220G, and 220B between a bank 240 and the second substrate 210 may function as a black matrix.

One surface of the bank 240 facing the first substrate 110 may be hydrophobic. Light (for example, monochromatic light) generated from a light source (e.g., an organic light-emitting device) may pass through a quantum dot layer and a color filter and may be converted into one color of red, green, and blue and emitted.

In forming the bank 240, a bank composition is applied on a substrate and cured, and then undergoes a photolithography process. The bank composition includes a curable polymer, a photoresist compound, a fluorine-containing polymer, a black pigment, a scattering agent, and a solvent, wherein, when the bank composition is cured, the solvent evaporates completely.

The filling material 300 is located between the first substrate 110 and the second substrate 210, wherein the filling material functions as both a gap maintainer that maintains an appropriate distance between the two substrates 110 and 210 and a bonding agent. Accordingly, when the filling material 300 is coated between the two substrates 110 and 210, which are then bonded together, the filling material 300 firmly bonds the two substrates 110 and 210 while properly maintaining a gap therebetween.

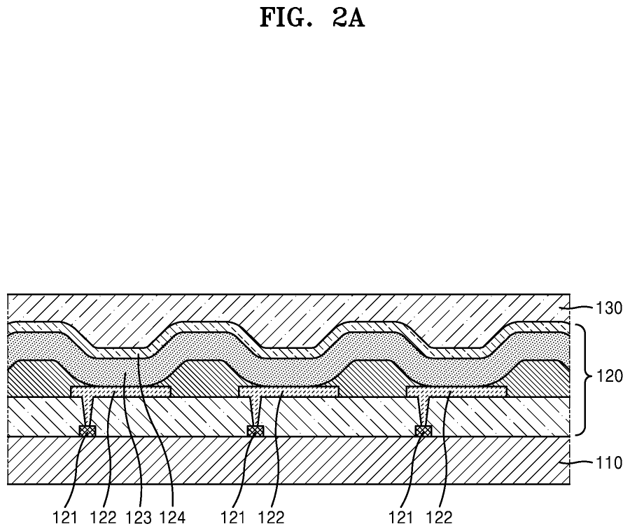

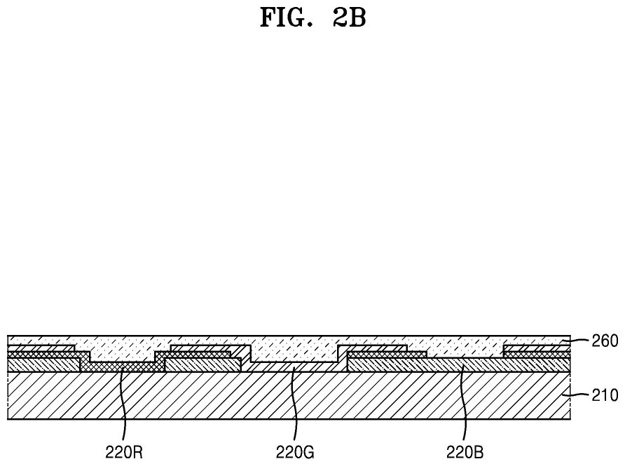

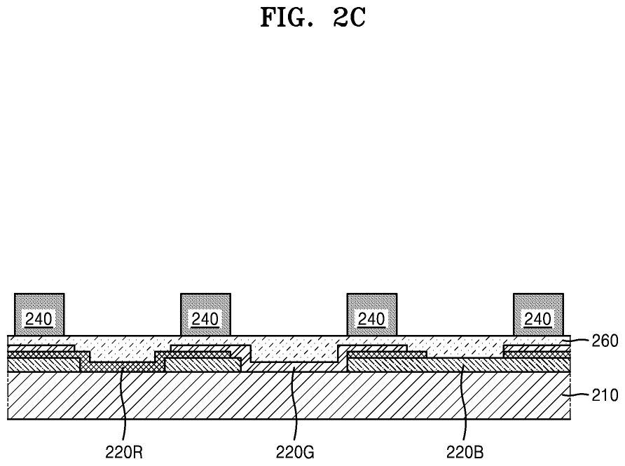

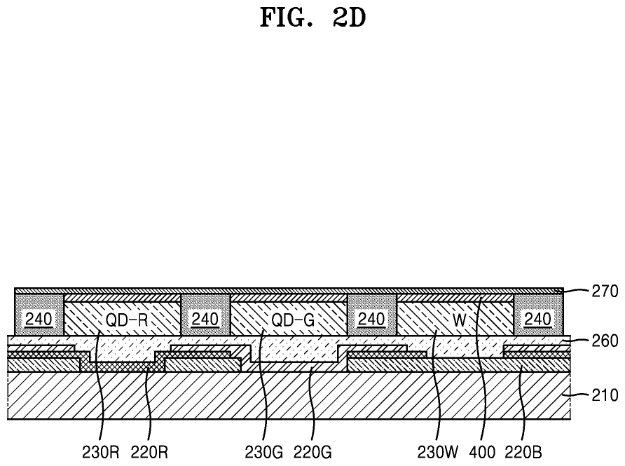

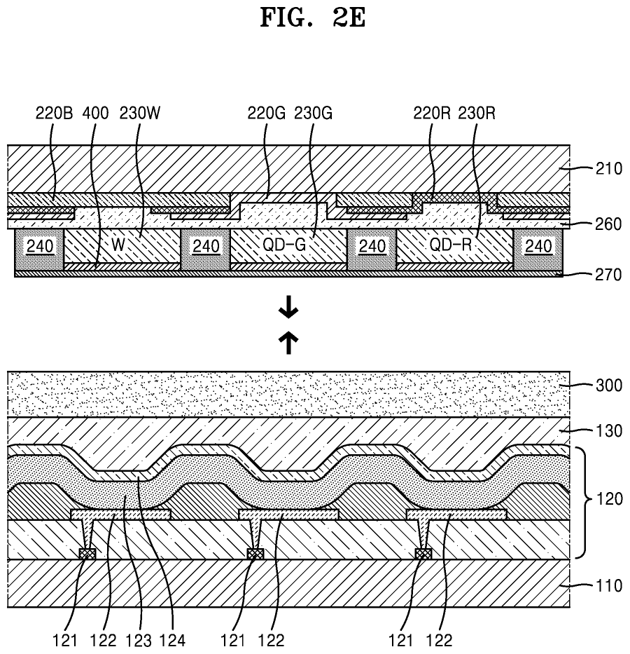

The display apparatus having the structure may be manufactured according to a process shown in FIGS. 2A to 2E.

First, as shown in FIG. 2A, the light-emitting device 120 may be formed on the first substrate 110, and may be covered by a thin-film encapsulation layer 130.

Then, the color filter layers 220R, 220G, and 220B may be patterned on the second substrate 210 as shown in FIG. 2B. The color filter layers 220R, 220G, and 220B may be formed at a position corresponding to the light-emitting device 120, and a partial region, in which the color filter layer 220R, the color filter layer 220G, and the color filter layer 220B may overlap, may serve as a black matrix. For example, a hollow silica material may be prepared on the color filter layers 220R, 220G, and 220B to form a low-refractive-index layer 260 on the color filter layers 220R, 220G, and 220B. The low-refractive-index layer 260 may have the refractive index of about 1.1 to about 1.5 and the thickness of about 0.1 μm to about 5 μm.

Next, on the low-refractive-index layer 260, as shown in FIG. 2C, the bank 240 may be patterned on a region where the color filter layers 220R, 220G, and 220B may overlap such that the bank 240 may remain for each position between the color filter layers 220R, 220G, and 220B between each pixel.

Next, as shown in FIG. 2D, the quantum dot layers 230R and 230G may be formed on a red pixel and a green pixel, and the scattering layer 230W may be formed on a blue pixel. Here, the quantum dot layers 230R and 230G may be formed at a position overlapping with the color filter layers 220R and 220G. The scattering layer 230W may be formed at a position overlapping with the color filter layer 220B. The quantum dot layers 230R and 230G and the scattering layer 230W may be formed by an inkjet process.

The quantum dot that is a photochromic particle included in the quantum dot layers 230R and 230G may include a group III-VI semiconductor compound; a group II-VI semiconductor compound; a group III-V semiconductor compound; a group III-VI semiconductor compound; a group semiconductor compound; a group IV-VI semiconductor compound; a group IV element or compound; or any combination thereof.

Examples of the group II-VI semiconductor compound may include a binary compound such as CdS, CdSe, CdTe, ZnS, ZnSe, ZnTe, ZnO, HgS, HgSe, HgTe, MgSe, or MgS; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS; a quaternary compound such as CdZnSeS, CdZnSeTe, CdZnSTe, CdHgSeS, CdHgSeTe, CdHgSTe, HgZnSeS, HgZnSeTe, or HgZnSTe; or any combination thereof.

Examples of the group III-V semiconductor compound may include a binary compound such as GaN, GaP, GaAs, GaSb, AlN, AlP, AlAs, AlSb, InN, InP, InAs, or InSb; a ternary compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, or InPSb; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb; or any combination thereof. In some embodiments, the group III-V semiconductor compound may further include a group II element. Examples of the group III-V semiconductor compound further including the group II element may include InZnP, InGaZnP, InAlZnP, and the like.

Examples of the III-VI group semiconductor compound may include a binary compound such as GaS, GaSe, Ga₂Se₃, GaTe, InS, InSe, In₂S₃, In₂Se₃, InTe, and the like; a ternary compound such as InGaS₃, InGaSe₃, and the like; or any combination thereof.

Examples of the group semiconductor compound may include a ternary compound such as AgInS, AgInS₂, CuInS, CuInS₂, CuGaO₂, AgGaO₂, AgAlO₂, a quaternary compound such as AgInGaS, or any combination thereof.

Examples of the group IV-VI semiconductor compound may include a binary compound such as SnS, SnSe, SnTe, PbS, PbSe, or PbTe; a ternary compound such as SnSeS, SnSeTe, SnSTe, PbSeS, PbSeTe, PbSTe, SnPbS, SnPbSe, or SnPbTe; a quaternary compound such as SnPbSSe, SnPbSeTe, or SnPbSTe; or any combination thereof.

The group IV element or compound may be a single element material such as Si or Ge; a binary compound such as SiC or SiGe; or any combination thereof.

Individual elements included in the multi-element compound, such as a binary compound, a ternary compound, and a quaternary compound, may be present in a particle thereof at a uniform or non-uniform concentration.

The quantum dot may have a single structure in which the concentration of each element included in the quantum dot is uniform or a core-shell double structure. In some embodiments, materials included in the core may be different from materials included in the shell.

The shell of the quantum dot may serve as a protective layer for preventing chemical denaturation of the core to maintain semiconductor characteristics and/or as a charging layer for imparting electrophoretic characteristics to the quantum dot. The shell may be a monolayer or a multilayer. An interface between a core and a shell may have a concentration gradient where a concentration of elements present in the shell decreases toward the core.

Examples of the shell of the quantum dot include metal, metalloid, or nonmetal oxide, a semiconductor compound, or a combination thereof. Examples of the metal oxide, metalloid, or nonmetal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound such as MgAl₂O₄, CoFe₂O₄, NiFe₂O₄, or CoMn₂O₄; and any combination thereof. Examples of the semiconductor compound may include a group II-VI semiconductor compound; a group III-V semiconductor compound; a group III-VI semiconductor compound; a group I-III-VI semiconductor compound; a group IV-VI semiconductor compound; or any combination thereof. In some embodiments, the semiconductor compound may be CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

The quantum dot may have a full width of half maximum (“FWHM”) of a spectrum of an emission wavelength of about 45 nm or less, about 40 nm or less, or about 30 nm or less. When the FWHM of the quantum dot is within this range, color purity or color reproducibility may be improved. In addition, because light emitted through the quantum dots is emitted in all directions, an optical viewing angle may be improved.

In addition, the quantum dot may be specifically, a spherical, pyramidal, multi-arm, or cubic nanoparticle, nanotube, nanowire, nanofiber, or nanoplate particle.

By adjusting the size of the quantum dot, the energy band gap may also be adjusted, thereby obtaining light of various wavelengths in the quantum dot emission layer. By using quantum dots of various sizes, a light-emitting device that may emit light of various wavelengths may be realized. In some embodiments, the size of the quantum dot may be selected such that the quantum dot may emit red, green, and/or blue light. In addition, the size of the quantum dot may be selected such that the quantum dot may emit white light by combining various light colors.

The scattering layer 230W may include, for example, titanium, silver, aluminum, or an oxide of any combination thereof.

After forming the quantum dot layers 230R and 230G and/or the scattering layer 230W, the organic capping layer 400 may be formed. The organic capping layer 400 may be, for example, formed by inkjet.

In some embodiments, the quantum dot layers 230R and 230G, the scattering layer 230W, and the organic capping layer 400 formed by inkjet may be crosslinked simultaneously (for example, less than 1 minute with ultraviolet (UV) of 390 nm) to thereby form the quantum dot layers 230R and 230G, the scattering layer 230W, and the organic capping layer 400 may be formed. By forming the organic capping layer 400, an N₂ atmosphere is not required until the inorganic capping layer 270 is formed.

Next, post-baking is performed, and the inorganic capping layer 270 may be formed on the organic capping layer 400 by vapor-phase chemical vapor deposition. In this embodiment, as the inorganic capping layer 270 may be formed by vapor-phase chemical vapor deposition on the formed organic capping layer 400, vapor-phase chemical vapor deposition may not affect the quantum dot layers 230R and 230G.

The inorganic capping layer 270 may be a layer including an oxide of Si, N, any combination thereof, or an oxide of any combination thereof and may have a thickness of about 1,000 Å to about 10,000 Å.

Next, as shown in FIG. 2E, the filling material 300 may be formed between the first and second substrates 110 and 210 and the two substrates 110 and 210 may be bonded together. Then, as shown in FIG. 1, a display apparatus having the light-emitting device 120 and the quantum dot layer 230R and 230G and the color filter layer 220R, 220G, and 220B may be implemented.

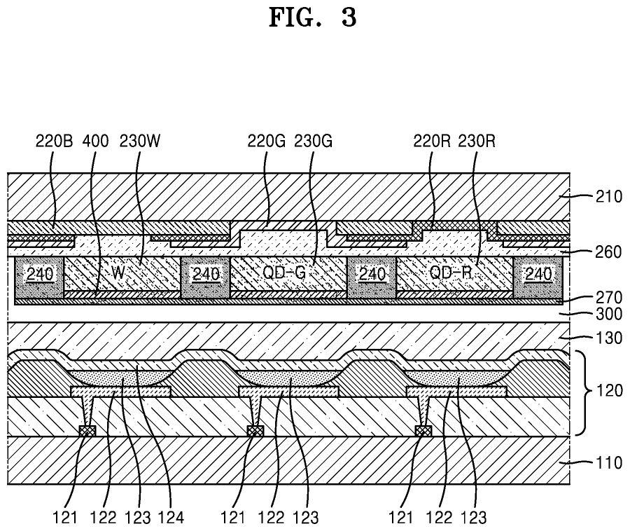

The present embodiment illustrates a case in which the interlayer 123 including the emission layer is formed as a common layer across the entire pixel area. However, as shown in FIG. 3, a modification example in which an interlayer is separately formed for each pixel is also possible. That is, the interlayer 123 including the emission layer may be formed as a common layer, or may be formed separately for each pixel.

The emission layer may include an organic light-emitting material or a light-emitting material.

The light-emitting device 120 will be described in detail.

### <First Electrode 122>

In FIG. 1, a substrate may be additionally located under the first electrode 122 or above the second electrode 124. The substrate may be a glass substrate or a plastic substrate.

The first electrode 122 may be formed by depositing or sputtering, on the substrate, a material for forming the first electrode 122. When the first electrode 122 is an anode, a high work function material that may easily inject holes may be used as a material for a first electrode.

The first electrode 122 may be a reflective electrode, a semi-transmissive electrode, or a transmissive electrode. When the first electrode 122 is a transmissive electrode, a material for forming the first electrode 122 may be indium tin oxide (“ITO”), indium zinc oxide (“IZO”), tin oxide (SnO₂), zinc oxide (ZnO), or any combinations thereof. In some embodiments, when the first electrode 122 is a semi-transmissive electrode or a reflective electrode, magnesium (Mg), silver (Ag), aluminum (Al), aluminum-lithium (Al—Li), calcium (Ca), magnesium-indium (Mg—In), magnesium-silver (Mg—Ag), or any combination thereof may be used as a material for forming the first electrode 122.

The first electrode 122 may have a single-layered structure consisting of a single layer or a multi-layered structure including two or more layers. In some embodiments, the first electrode 122 may have a triple-layered structure of ITO/Ag/ITO.

### <Interlayer 123>

The interlayer 123 may be on the first electrode 122. The interlayer 123 may include an emission layer.

The interlayer 123 may further include a hole transport region between the first electrode 122 and the emission layer and an electron transport region between the emission layer and the second electrode 124.

The interlayer 123 may further include metal-containing compounds such as organometallic compounds, inorganic materials such as quantum dots, and the like, in addition to various organic materials.

The interlayer 123 may include: i) at least two emitting units sequentially stacked between the first electrode 122 and the second electrode 124; and ii) a charge generation layer located between the at least two emitting units. When the interlayer 123 includes the at least two emitting units and a charge generation layer, the light-emitting device 120 may be a tandem light-emitting device.

### <Hole Transport Region in Interlayer 123>

The hole transport region may have i) a single-layered structure consisting of a single layer consisting of a single material, ii) a single-layered structure consisting of a single layer including a plurality of different materials, or iii) a multi-layered structure having a plurality of layers including a plurality of different materials.

The hole transport region may include a hole injection layer, a hole transport layer, an emission auxiliary layer, an electron blocking layer, or a combination thereof.

In an embodiment, for example, the hole transport region may have a multi-layered structure, e.g., a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein layers of each structure are sequentially stacked on the first electrode 122 in each stated order.

The hole transport region may include the compound represented by Formula 201, the compound represented by Formula 202, or any combination thereof:

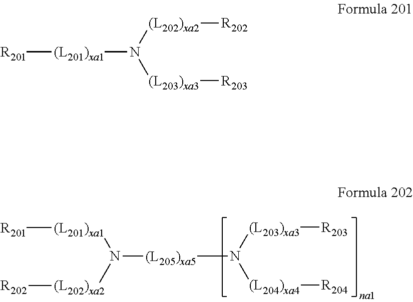

wherein, in Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be bound to each other via a single bond, a C₁-C₅ alkylene group unsubstituted or substituted with at least one R₁₀ₐ, or a C₂-C₅ alkenylene group unsubstituted or substituted with at least one R₁₀ₐ to form a C₈-C₆₀ polycyclic group (e.g., a carbazole group or the like) unsubstituted or substituted with at least one R₁₀ₐ (e.g., Compound HT16 described herein),
R₂₀₃ and R₂₀₄ may optionally be bound to each other via a single bond, a C₁-C₅ alkylene group unsubstituted or substituted with at least one R₁₀ₐ, or a C₂-C₅ alkenylene group unsubstituted or substituted with at least one R₁₀ₐ to form a C₈-C₆₀ polycyclic group unsubstituted or substituted with at least one R₁₀ₐ, and
na1 may be an integer from 1 to 4.

In some embodiments, Formulae 201 and 202 may each include at least one of groups represented by Formulae CY201 to CY217:

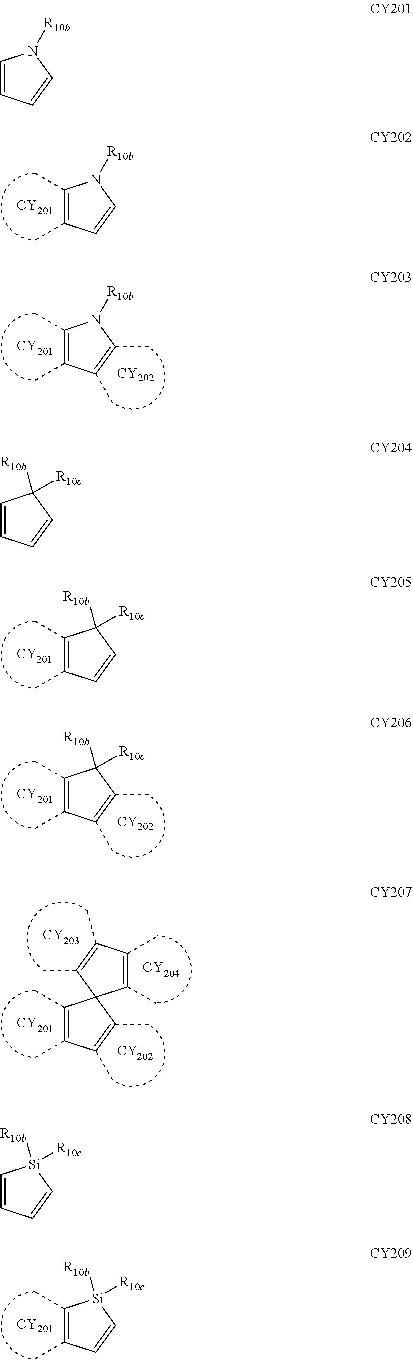

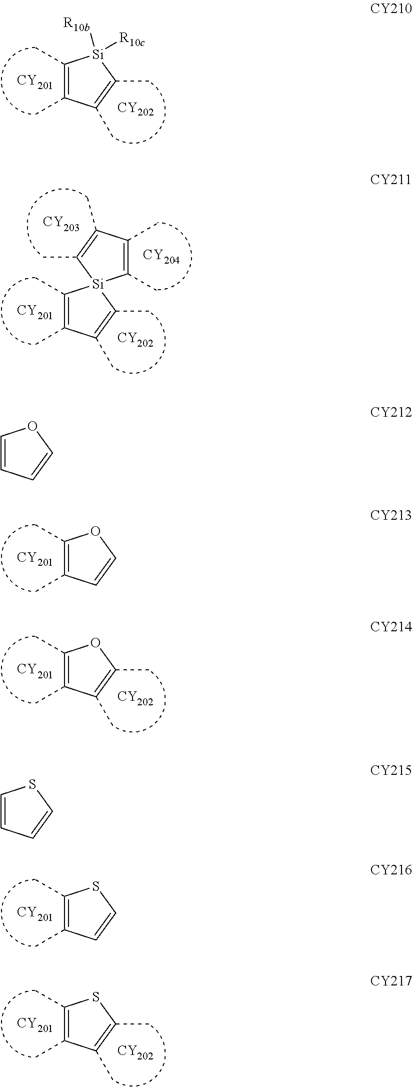

wherein, in Formulae CY201 to CY217, R_{10b} and R_{10c} may each be understood by referring to the descriptions of R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

The thickness of the hole transport region may be in a range of about 50 Angstroms (Å) to about 10,000 Å, for example, about 100 Å to about 4,000 Å. When the hole transport region includes a hole injection layer, a hole transport layer, and any combination thereof, the thickness of the hole injection layer may be in a range of about 100 Å to about 9,000 Å, for example, about 100 Å to about 1,000 Å, the thickness of the hole transport layer may be in a range of about 50 Å to about 2,000 Å, for example, about 100 Å to about 1,500 Å. When the thicknesses of the hole transport region, the hole injection layer, and the hole transport layer are within any of these ranges, excellent hole transport characteristics may be obtained without a substantial increase in driving voltage.

The emission auxiliary layer may increase light emission efficiency by compensating for an optical resonance distance according to the wavelength of light emitted by an emission layer. The electron blocking layer may prevent leakage of electrons to a hole transport region from the emission layer. Materials that may be included in the hole transport region may also be included in an emission auxiliary layer and an electron blocking layer.

<p-Dopant>

The hole transport region may include a charge generating material as well as the aforementioned materials to improve conductive properties of the hole transport region. The charge generating material may be substantially homogeneously or non-homogeneously dispersed (for example, as a single layer consisting of charge generating material) in the hole transport region.

The charge generating material may include, for example, a p-dopant.

In some embodiments, a lowest unoccupied molecular orbital (“LUMO”) energy level of the p-dopant may be −3.5 electron volts (eV) or less.

In some embodiments, the p-dopant may include a quinone derivative, a compound containing a cyano group, a compound containing element EL1 and element EL2, or any combination thereof.

Examples of the quinone derivative may include TCNQ, F4-TCNQ, and the like.

Examples of the compound containing a cyano group include HAT-CN, a compound represented by Formula 221, and the like:

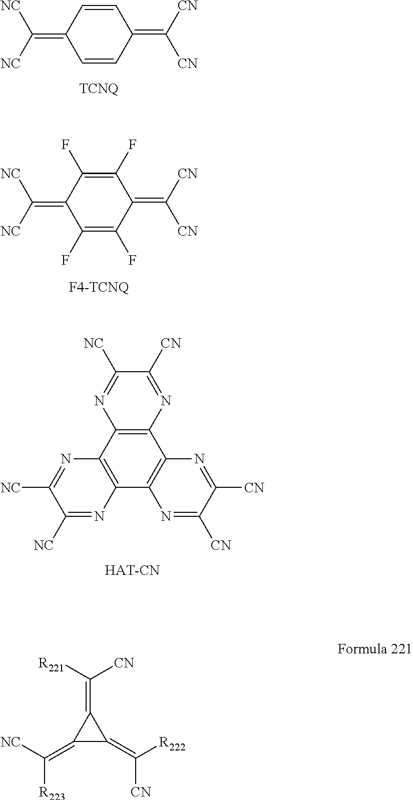

wherein, in Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and at least one of R₂₂₁ to R₂₂₃ may each independently be: a C₃-C₆₀ carbocyclic group or a C₁-C₆₀ heterocyclic group, substituted with a cyano group; —F; —Cl; —Br; —I; a C₁-C₂₀ alkyl group substituted with a cyano group, —F, —Cl, —Br, —I, or any combination thereof; or any combination thereof.

In the compound containing element EL1 and element EL2, element EL1 may be a metal, a metalloid, or a combination thereof, and element EL2 may be non-metal, a metalloid, or a combination thereof.

### <Emission Layer in Interlayer 123>

When the light-emitting device 120 is a full color light-emitting device, the emission layer may be patterned into a red emission layer, a green emission layer, and/or a blue emission layer, according to a sub-pixel. In one or more embodiments, the emission layer may have a stacked structure. The stacked structure may include two or more layers selected from a red emission layer, a green emission layer, and a blue emission layer. The two or more layers may be in direct contact with each other. In some embodiments, the two or more layers may be separated from each other. In one or more embodiments, the emission layer may include two or more materials. The two or more materials may include a red light-emitting material, a green light-emitting material, or a blue light-emitting material. The two or more materials may be mixed with each other in a single layer. The two or more materials mixed with each other in the single layer may emit white light.

The emission layer may include a host and a dopant. The dopant may be a phosphorescent dopant, a fluorescent dopant, or any combination thereof.

The amount of the dopant in the emission layer may be in a range of about 0.01 parts to about 15 parts by weight based on 100 parts by weight of the host.

In some embodiments, the emission layer may include a quantum dot. The quantum dot may be understood by referring to the description of the quantum dot provided herein.

The emission layer may include a delayed fluorescence material. The delayed fluorescence material may serve as a host or a dopant in the emission layer.

The thickness of the emission layer may be in a range of about 100 Å to about 1,000 Å, and in some embodiments, about 200 Å to about 600 Å. When the thickness of the emission layer is within any of these ranges, improved luminescence characteristics may be obtained without a substantial increase in driving voltage.

### <Host>

The host may include a compound represented by Formula 301:

[Ar₃₀₁]_{xb11}-[(L₃₀₁)_{xb1}-R₃₀₁]_{xb21} Formula 301
wherein, in Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ may each be understood by referring to the description of Q₁ provided herein.

In some embodiments, when xb11 in Formula 301 is 2 or greater, at least two Ar₃₀₁(s) may be bound via a single bond.

In some embodiments, the host may include a compound represented by Formula 301-1, a compound represented by Formula 301-2, or any combination thereof:

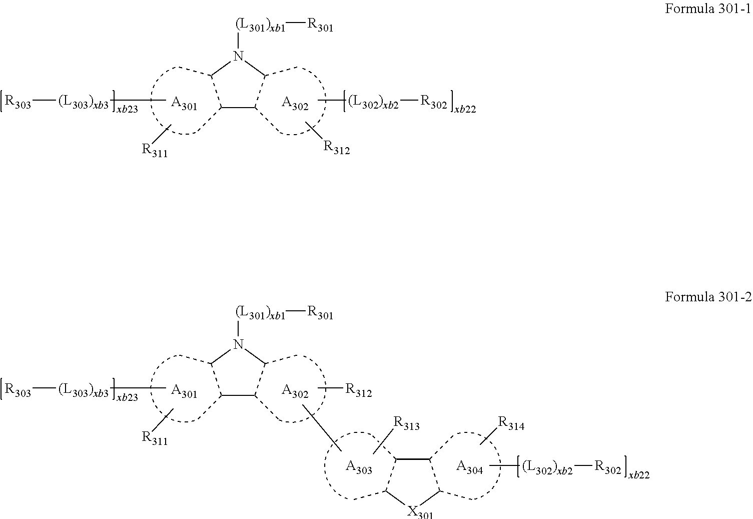

wherein, in Formulae 301-1 to 301-2,
ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N-[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may be understood by referring to the descriptions of L₃₀₁, xb1, and R₃₀₁ provided herein, respectively,
L₃₀₂ to L₃₀₄ may each be understood by referring to the description of L₃₀₁ provided herein,
xb2 to xb4 may each be understood by referring to the description of xb1 provided herein, and
R₃₀₂ to R₃₀₅ and R₃₁₁ to R₃₁₄ may each be understood by referring to the description of R₃₀₁ provided herein.

### <Phosphorescent Dopant>

The phosphorescent dopant may include at least one transition metal as a center metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In some embodiments, the phosphorescent dopant may include an organometallic complex represented by Formula 401:

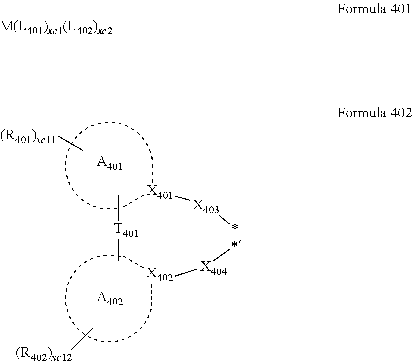

wherein, in Formulae 401 and 402,
M may be transition metal (e.g., iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, and when xc1 is 2 or greater, at least two L₄₀₁(s) may be identical to or different from each other, L₄₀₂ may be an organic ligand, and xc2 may be an integer from 0 to 4, and when xc2 is 2 or greater, at least two L₄₀₂(s) may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, —O—, —C(═O)—, —C(Q₄₁₁)(Q₄₁₂)-, —C(Q₄₁₁)=C(Q₄₁₂)-, —C(Q₄₁₁)=, or =C═,
X₄₀₃ and X₄₀₄ may each independently be a chemical bond (e.g., a covalent bond or a coordinate bond), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ may each be understood by referring to the description of Q₁ provided herein,
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each be understood by referring to the description of Q₁ provided herein,
xc11 and xc12 may each independently be an integer from 0 to 10, and
* and *′ in Formula 402 each indicate a binding site to M in Formula 401.

In one or more embodiments, in Formula 402, i) X₄₀₁ may be nitrogen, and X₄₀₂ may be carbon, or ii) X₄₀₁ and X₄₀₂ may both be nitrogen.

In one or more embodiments, when xc1 in Formula 402 is 2 or greater, two ring A₄₀₁(s) of at least two L₄₀₁ (s) may optionally be bound via T₄₀₂ as a linking group, or two ring A₄₀₂(s) may optionally be bound via T₄₀₃ as a linking group (see Compounds PD1 to PD4 and PD7). T₄₀₂ and T₄₀₃ may each be understood by referring to the description of T₄₀₁ provided herein.

L₄₀₂ in Formula 401 may be any suitable organic ligand. For example, L₄₀₂ may be a halogen group, a diketone group (e.g., an acetylacetonate group), a carboxylic acid group (e.g., a picolinate group), —C(═O), an isonitrile group, —CN, or a phosphorus group (e.g., a phosphine group or a phosphite group).

### <Fluorescent Dopant>

The fluorescent dopant may include an amine group-containing compound, a styryl group-containing compound, or any combination thereof.

In some embodiments, the fluorescent dopant may include a compound represented by Formula 501:

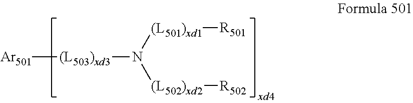

wherein, in Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

In some embodiments, in Formula 501, Ar₅₀₁ may include a condensed ring group (e.g., an anthracene group, a chrysene group, or a pyrene group) in which at least three monocyclic groups are condensed.

In some embodiments, xd4 in Formula 501 may be 2.

### <Delayed Fluorescence Material>

The emission layer may include a delayed fluorescence material.

The delayed fluorescence material described herein may be any suitable compound that may emit delayed fluorescence according to a delayed fluorescence emission mechanism.

The delayed fluorescence material included in the emission layer may serve as a host or a dopant, depending on types of other materials included in the emission layer.

In some embodiments, a difference between a triplet energy level (electron volts [eV]) of the delayed fluorescence material and a singlet energy level (eV) of the delayed fluorescence material may be about 0 eV or greater and about 0.5 eV or less. When the difference between a triplet energy level (eV) of the delayed fluorescence material and a singlet energy level (eV) of the delayed fluorescence material is within this range, up-conversion from a triplet state to a singlet state in the delayed fluorescence material may be effectively occurred, thus improving luminescence efficiency and the like of the light-emitting device 120.

In some embodiments, the delayed fluorescence material may include: i) a material including at least one electron donor (e.g., a π electron-rich C₃-C₆₀ cyclic group such as a carbazole group and the like) and at least one electron acceptor (e.g., a sulfoxide group, a cyano group, a π electron-deficient nitrogen-containing C₁-C₆₀ cyclic group, and the like), ii) a material including a C₈-C₆₀ polycyclic group including at least two cyclic groups condensed to each other and sharing boron (B), and the like.

### <Electron Transport Region in Interlayer 123>

The electron transport region may have i) a single-layered structure consisting of a single layer consisting of a single material, ii) a single-layered structure consisting of a single layer including a plurality of different materials, or iii) a multi-layered structure having a plurality of layers including a plurality of different materials.

The electron transport region may include a buffer layer, a hole blocking layer, an electron control layer, an electron transport layer, or an electron injection layer.

In some embodiments, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein layers of each structure are sequentially stacked on the emission layer in each stated order.

The electron transport region (e.g., a buffer layer, a hole blocking layer, an electron control layer, or an electron transport layer in the electron transport region) may include a metal-free compound including at least one π electron-deficient nitrogen-containing C₁-C₆₀ cyclic group.

In some embodiments, the electron transport region may include a compound represented by Formula 601:

[Ar₆₀₁]ₓₑ₁₁-[(L₆₀₁)ₓₑ₁-R₆₀₁]ₓₑ₂₁ Formula 601
wherein, in Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each be understood by referring to the description of Q₁ provided herein,
xe21 may be 1, 2, 3, 4, or 5, and
at least one of Arm, L₆₀₁, and R₆₀₁ may independently be a π electron-deficient nitrogen-containing C₁-C₆₀ cyclic group unsubstituted or substituted with at least one R₁₀ₐ.

In some embodiments, when xe11 in Formula 601 is 2 or greater, at least two Ar₆₀₁(s) may be bound via a single bond.

In some embodiments, in Formula 601, Ar₆₀₁ may be a substituted or unsubstituted anthracene group.

In some embodiments, the electron transport region may include a compound represented by Formula 601-1:

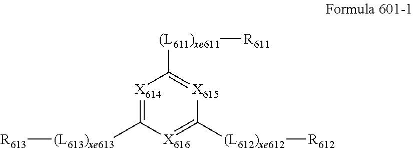

wherein, in Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,
L₆₁₁ to L₆₁₃ may each be understood by referring to the description of L₆₀₁ provided herein,
xe611 to xe613 may each be understood by referring to the description of xe1 provided herein,
R₆₁₁ to R₆₁₃ may each be understood by referring to the description of R₆₀₁ provided herein, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

In an embodiment, for example, in Formulae 601 and 601-1, xe1 and xe611 to xe613 may each independently be 0, 1, or 2.

The thickness of the electron transport region may be in a range of about 100 Angstroms (Å) to about 5,000 Å, for example, about 160 Å to about 4,000 Å. When the electron transport region includes a buffer layer, a hole blocking layer, an electron control layer, an electron transport layer, or any combination thereof, the thicknesses of the buffer layer, the hole blocking layer, or the electron control layer may each independently be in a range of about 20 Å to about 1,000 Å, for example, about 30 Å to about 300 Å, and the thickness of the electron transport layer may be in a range of about 100 Å to about 1,000 Å, for example, about 150 Å to about 500 Å. When the thicknesses of the buffer layer, the hole blocking layer, the electron control layer, the electron transport layer, and/or the electron transport layer are each within these ranges, excellent electron transport characteristics may be obtained without a substantial increase in driving voltage.

The electron transport region (for example, the electron transport layer in the electron transport region) may further include, in addition to the materials described above, a metal-containing material.

The metal-containing material may include an alkali metal complex, an alkaline earth metal complex, or any combination thereof. A metal ion of the alkali metal complex may be a lithium (Li) ion, a sodium (Na) ion, a potassium (K) ion, a rubidium (Rb) ion, or a cesium (Cs) ion. A metal ion of the alkaline earth metal complex may be a beryllium (Be) ion, a magnesium (Mg) ion, a calcium (Ca) ion, a strontium (Sr) ion, or a barium (Ba) ion. Each ligand coordinated with the metal ion of the alkali metal complex and the alkaline earth metal complex may independently be hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzimidazole, hydroxyphenylbenzothiazole, bipyridine, phenanthroline, cyclopentadiene, or any combination thereof.

In an embodiment, for example, the metal-containing material may include a Li complex. The Li complex may include, e.g., Compound ET-D1 (LiQ) or Compound ET-D2:

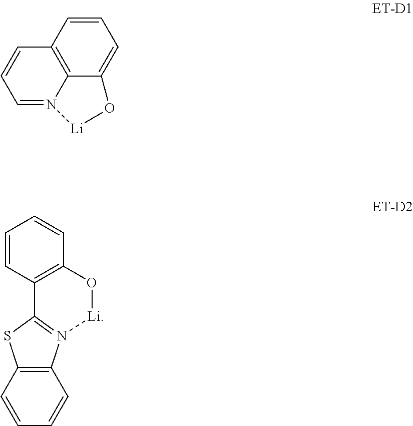

The electron transport region may include an electron injection layer that facilitates injection of electrons from the second electrode 124. The electron injection layer may be in direct contact with the second electrode 124.

The electron injection layer may have i) a single-layered structure consisting of a single layer consisting of a single material, ii) a single-layered structure consisting of a single layer including a plurality of different materials, or iii) a multi-layered structure having a plurality of layers including a plurality of different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may be Li, Na, K, Rb, Cs or any combination thereof. The alkaline earth metal may be Mg, Ca, Sr, Ba, or any combination thereof. The rare earth metal may be Sc, Y, Ce, Tb, Yb, Gd, or any combination thereof.

The alkali metal-containing compound, the alkaline earth metal-containing compound, and the rare earth metal-containing compound may be oxides, halides (e.g., fluorides, chlorides, bromides, or iodides), tellurides, or any combination thereof of each of the alkali metal, the alkaline earth metal, and the rare earth metal, respectively.

The alkali metal-containing compound may be alkali metal oxides such as Li₂O, Cs₂O, or K₂O, alkali metal halides such as LiF, NaF, CsF, KF, LiI, NaI, CsI, or Kl, or any combination thereof. The alkaline earth-metal-containing compound may include alkaline earth-metal oxides, such as BaO, SrO, CaO, BaₓSr₁₋ₓO (wherein x is a real number satisfying 0<x<1), or BaₓCa₁₋ₓO (wherein x is a real number satisfying 0<x<1). The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In some embodiments, the rare earth metal-containing compound may include a lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and the like.

The alkali metal complex, the alkaline earth metal complex, and the rare earth metal complex may include: i) one of ions of the alkali metal, alkaline earth metal, and rare earth metal described above and ii) a ligand bond to the metal ion, e.g., hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzimidazole, hydroxyphenylbenzothiazole, bipyridine, phenanthroline, cyclopentadiene, or any combination thereof.

The electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In some embodiments, the electron injection layer may further include an organic material (e.g., a compound represented by Formula 601).

In some embodiments, the electron injection layer may consist of i) an alkali metal-containing compound (e.g., alkali metal halide), or ii) a) an alkali metal-containing compound (e.g., alkali metal halide); and b) an alkali metal, an alkaline earth metal, a rare earth metal, or any combination thereof. In some embodiments, the electron injection layer may be a Kl:Yb co-deposition layer, a RbI:Yb co-deposition layer, or the like.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth metal complex, the rare earth metal complex, or any combination thereof may be homogeneously or non-homogeneously dispersed in a matrix including the organic material.

The thickness of the electron injection layer may be in a range of about 1 Å to about 100 Å, and in some embodiments, about 3 Å to about 90 Å. When the thickness of the electron injection layer is within any of these ranges, excellent electron injection characteristics may be obtained without a substantial increase in driving voltage.

### <Second Electrode 124>

The second electrode 124 may be on the interlayer 123. In an embodiment, the second electrode 124 may be a cathode that is an electron injection electrode. In this embodiment, a material for forming the second electrode 124 may be a material having a low work function, for example, a metal, an alloy, an electrically conductive compound, or any combination thereof.

The second electrode 124 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 124 may be a transmissive electrode, a semi-transmissive electrode, or a reflective electrode.

The second electrode 124 may have a single-layered structure, or a multi-layered structure including two or more layers.

### <Capping Layer>

A first capping layer may be located outside the first electrode 122, and/or a second capping layer may be located outside the second electrode 124. In some embodiments, the light-emitting device 120 may have a structure in which the first capping layer, the first electrode 122, the interlayer 123, and the second electrode 124 are sequentially stacked in this stated order, a structure in which the first electrode 122, the interlayer 123, the second electrode 124, and the second capping layer are sequentially stacked in this stated order, or a structure in which the first capping layer, the first electrode 122, the interlayer 123, the second electrode 124, and the second capping layer are sequentially stacked in this stated order.

In the light-emitting device 120, light emitted from the emission layer in the interlayer 123 may pass through the first electrode 122 (which may be a semi-transmissive electrode or a transmissive electrode) and through the first capping layer to the outside. In the light-emitting device 120, light emitted from the emission layer in the interlayer 123 may pass through the second electrode 124 (which may be a semi-transmissive electrode or a transmissive electrode) and through the second capping layer to the outside.

The first capping layer and the second capping layer may improve the external luminescence efficiency based on the principle of constructive interference. Accordingly, the optical extraction efficiency of the light-emitting device 120 may be increased, thus improving the luminescence efficiency of the light-emitting device 120.

The first capping layer and the second capping layer may each include a material having a refractive index of 1.6 or higher (at 589 nm).

The first capping layer and the second capping layer may each independently be a capping layer including an organic material, an inorganic capping layer including an inorganic material, or a composite capping layer including an organic material and an inorganic material.

At least one of the first capping layer and the second capping layer may each independently include carbocyclic compounds, heterocyclic compounds, amine group-containing compounds, porphine derivatives, phthalocyanine derivatives, naphthalocyanine derivatives, alkali metal complexes, alkaline earth metal complexes, or any combination thereof. The carbocyclic compound, the heterocyclic compound, and the amine group-containing compound may optionally be substituted with a substituent of O, N, S, Se, Si, F, Cl, Br, I, or any combination thereof. In some embodiments, at least one of the first capping layer and the second capping layer may each independently include an amine group-containing compound.

In some embodiments, at least one of the first capping layer and the second capping layer may each independently include the compound represented by Formula 201, the compound represented by Formula 202, or any combination thereof.

### <Manufacturing Method>

The layers constituting the hole transport region, the emission layer, and the layers constituting the electron transport region may be formed in a specific region by using one or more suitable methods such as vacuum deposition, spin coating, casting, Langmuir-Blodgett (“LB”) deposition, ink-jet printing, laser printing, and laser-induced thermal imaging.

When layers constituting the hole transport region, an emission layer, and layers constituting the electron transport region are each independently formed by vacuum-deposition, the vacuum-deposition may be performed at a deposition temperature in a range of about 100° C. to about 500° C., at a vacuum degree in a range of about 10⁻⁸ torr to about 10⁻³ torr, and at a deposition rate in a range of about 0.01 Angstroms per second (A/sec) to about 100 Å/sec, depending on the material to be included in each layer and the structure of each layer to be formed.

When layers constituting the hole transport region, the emission layer, and layers constituting the electron transport region are each independently formed by spin coating, the spin coating may be performed at a coating rate of about 2,000 revolutions per minute (rpm) to about 5,000 rpm and at a heat treatment temperature of about 80° C. to 200° C., depending on the material to be included in each layer and the structure of each layer to be formed.

### General Definitions of Terms

The term “C₃-C₆₀ carbocyclic group” as used herein refers to a cyclic group consisting of carbon atoms only and having 3 to 60 carbon atoms as ring-forming atoms. The term “C₁-C₆₀ heterocyclic group” as used herein refers to a cyclic group having 1 to 60 carbon atoms in addition to a heteroatom as ring-forming atoms other than carbon atoms. The C₃-C₆₀ carbocyclic group and the C₁-C₆₀ heterocyclic group may each be a monocyclic group consisting of one ring or a polycyclic group in which at least two rings are condensed. For example, the number of ring-forming atoms in the C₁-C₆₀ heterocyclic group may be in a range of 3 to 61.

The term “cyclic group” as used herein may include the C₃-C₆₀ carbocyclic group and the C₁-C₆₀ heterocyclic group.

The term “T₁ electron-rich C₃-C₆₀ cyclic group” refers to a cyclic group having 3 to 60 carbon atoms and not including *—N=*′ as a ring-forming moiety. The term “T₁ electron-deficient nitrogen-containing C₁-C₆₀ cyclic group” as used herein refers to a heterocyclic group having 1 to 60 carbon atoms and *—N=*′ as a ring-forming moiety.

In some embodiments,
the C₃-C₆₀ carbocyclic group may be i) a T₁ group or ii) a group in which at least two T₁ groups are condensed (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) a T2 group, ii) a group in which at least two T2 groups are condensed, or iii) a group in which at least one T2 group is condensed with at least one T1 group (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonapthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and the like),
the π electron-rich C₃-C₆₀ cyclic group may be i) a T1 group, ii) a condensed group in which at least two T1 groups are condensed, iii) a T3 group, iv) a condensed group in which at least two T3 groups are condensed, or v) a condensed group in which at least one T3 group is condensed with at least one T1 group (for example, a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonapthothiophene group, a benzonaphthosilole group, a benzofurodibenzofuran group, a benzofurodibenzothiophene group, a benzothienodibenzothiophene group, and the like), and
the π electron-deficient nitrogen-containing C₁-C₆₀ cyclic group may be i) a T4 group, ii) a group in which at least two T4 groups are condensed, iii) a group in which at least one T4 group is condensed with at least one T1 group, iv) a group in which at least one T4 group is condensed with at least one T3 group, or v) a group in which at least one T4 group, at least one T1 group, and at least one T3 group are condensed (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and the like),
Here, the T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
the T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
the T3 group may be a furan group, a thiophene group, a 1H-pyrrole group, a silole group, or a borole group, and
the T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The term “cyclic group”, “C₃-C₆₀ carbocyclic group”, “C₁-C₆₀ heterocyclic group”, “π electron-rich C₃-C₆₀ cyclic group”, or “π electron-deficient nitrogen-containing C₁-C₆₀ cyclic group” as used herein may be a group condensed with any suitable cyclic group, a monovalent group, or a polyvalent group (e.g., a divalent group, a trivalent group, a quadvalent group, or the like), depending on the structure of the formula to which the term is applied. For example, a “benzene group” may be a benzene ring, a phenyl group, a phenylene group, or the like, and this may be understood by one of ordinary skill in the art, depending on the structure of the formula including the “benzene group”.

Examples of the monovalent C₃-C₆₀ carbocyclic group and the monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a heteroaryl group, a monovalent non-aromatic condensed polycyclic group, and a monovalent non-aromatic condensed heteropolycyclic group. Examples of the divalent C₃-C₆₀ carbocyclic group and the divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein refers to a linear or branched aliphatic hydrocarbon monovalent group having 1 to 60 carbon atoms, and examples thereof include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an iso-nonyl group, a sec-nonyl group, a tert-nonyl group, an n-decyl group, an isodecyl group, a sec-decyl group, and a tert-decyl group. The term “C₁-C₆₀ alkylene group” as used herein refers to a divalent group having the same structure as the C₁-C₆₀ alkyl group.

The term “C₂-C₆₀ alkenyl group” as used herein refers to a hydrocarbon group having at least one carbon-carbon double bond in the middle or at the terminus of the C₂-C₆₀ alkyl group. Examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a monovalent hydrocarbon group having at least one carbon-carbon triple bond in the middle or at the terminus of the C₂-C₆₀ alkyl group. Examples thereof include an ethynyl group and a propynyl group. The term “C₂-C₆₀ alkynylene group” as used herein refers to a divalent group having the same structure as the C₂-C₆₀ alkynyl group.

The term “C₁-C₆₀ alkoxy group” as used herein refers to a monovalent group represented by —OA₁₀₁ (wherein A₁₀₁ is a C₁-C₁ alkyl group). Examples thereof include a methoxy group, an ethoxy group, and an isopropyloxy group.

The term “C₃-C₁₀ cycloalkyl group” as used herein refers to a monovalent saturated hydrocarbon monocyclic group including 3 to 10 carbon atoms. Examples of the C₃-C₁₀ cycloalkyl group as used herein include a cyclopropyl group, a cyclobutyl group, a cyclopentyl group, a cyclohexyl group, a cycloheptyl group, a cyclooctyl group, an adamantanyl group, a norbornanyl (bicyclo[2.2.1]heptyl) group, a bicyclo[1.1.1]pentyl group, a bicyclo[2.1.1]hexyl group, or a bicyclo[2.2.2]octyl group. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent cyclic group including at least one heteroatom other than carbon atoms as a ring-forming atom and having 1 to 10 carbon atoms. Examples thereof include a 1,2,3,4-oxatriazolidinyl group, a tetrahydrofuranyl group, and a tetrahydrothiophenyl group. The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein refers to a monovalent cyclic group that has 3 to 10 carbon atoms and at least one carbon-carbon double bond in its ring, and is not aromatic. Examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent cyclic group including at least one heteroatom other than carbon atoms as a ring-forming atom, 1 to 10 carbon atoms, and at least one double bond in its ring. Examples of the heterocycloalkenyl group include a 4,5-dihydro-1,2,3,4-oxatriazolyl group, a 2,3-dihydrofuranyl group, and a 2,3-dihydrothiophenyl group. The term “C₁-C₁₀ heterocycloalkylene group” as used herein refers to a divalent group having the same structure as the C₁-C₁₀ heterocycloalkyl group.

The term “C₆-C₆₀ aryl group” as used herein refers to a monovalent group having a carbocyclic aromatic system having 6 to 60 carbon atoms. The term “C₆-C₆₀ arylene group” as used herein refers to a divalent group having a carbocyclic aromatic system having 6 to 60 carbon atoms. Examples of the C₆-C₆₀ aryl group include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. When the C₆-C₆₀ aryl group and the C₆-C₆₀ arylene group each independently include two or more rings, the respective rings may be fused.

The term “C₁-C₆₀ heteroaryl group” as used herein refers to a monovalent group having a heterocyclic aromatic system further including at least one heteroatom other than carbon atoms as a ring-forming atom and 1 to 60 carbon atoms. The term “C₁-C₆₀ heteroarylene group” as used herein refers to a divalent group having a heterocyclic aromatic system further including at least one heteroatom other than carbon atoms as a ring-forming atom and 1 to 60 carbon atoms. Examples of the C₁-C₆₀ heteroaryl group include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each independently include two or more rings, the respective rings may be fused.

The term “monovalent non-aromatic condensed polycyclic group” as used herein refers to a monovalent group that has two or more condensed rings and only carbon atoms (e.g., 8 to 60 carbon atoms) as ring forming atoms, wherein the molecular structure when considered as a whole is non-aromatic. Examples of the monovalent non-aromatic condensed polycyclic group include an indenyl group, a fluorenyl group, a spiro-bifluorenyl group, a benzofluorenyl group, an indenophenanthrenyl group, and an indenoanthracenyl group. The term “divalent non-aromatic condensed polycyclic group” as used herein refers to a divalent group having substantially the same structure as the monovalent non-aromatic condensed polycyclic group.

The term “monovalent non-aromatic condensed heteropolycyclic group” as used herein refers to a monovalent group that has two or more condensed rings and at least one heteroatom other than carbon atoms (e.g., 1 to 60 carbon atoms), as a ring-forming atom, wherein the molecular structure when considered as a whole is non-aromatic. Examples of the monovalent non-aromatic condensed heteropolycyclic group include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzooxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as used herein refers to a divalent group having substantially the same structure as the monovalent non-aromatic condensed heteropolycyclic group.

The term “C₆-C₆₀ aryloxy group” as used herein is represented by —OA₁₀₂ (wherein A₁₀₂ is the C₆-C₆₀ aryl group). The term “C₆-C₆₀ arylthio group” as used herein is represented by —SA₁₀₃ (wherein A₁₀₃ is the C₆-C₆₀ aryl group).

The term “C₇-C₆₀ aryl alkyl group” used herein refers to -A₁₀₄A₁₀₅ (where A₁₀₄ may be a C₁-C₅₄ alkylene group, and A₁₀₅ may be a C₆-C₅₉ aryl group), and the term “C₂-C₆₀ heteroaryl alkyl group” used herein refers to -A₁₀₆A₁₀₇ (where A₁₀₆ may be a C₁-C₅₉ alkylene group, and A₁₀₇ may be a C₁-C₅₉ heteroaryl group).

The term “R₁₀ₐ” as used herein may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a Co-Coo aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).
Q₁ to Q₃, Q₁₁ to Q₁₃, Q₂₁ to Q₂₃ and Q₃₁ to Q₃₃ may each independently be: hydrogen; deuterium; —F; —C₁; —Br; —I; a hydroxyl group; a cyano group; a nitro group; a C₁-Coo alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ aryl alkyl group; or a C₂-C₆₀ heteroaryl alkyl group.

The term “heteroatom” as used herein refers to any atom other than a carbon atom. Examples of the heteroatom may include O, S, N, P, Si, B, Ge, Se, or any combination thereof.

A third-row transition metal as used herein may include hafnium (Hf), tantalum (Ta), tungsten (W), rhenium (Re), osmium (Os), iridium (Ir), platinum (Pt), or gold (Au).

“Ph” used herein represents a phenyl group, “Me” used herein represents a methyl group, “Et” used herein represents an ethyl group, “ter-Bu” or “But” used herein represents a tert-butyl group, and “OMe” used herein represents a methoxy group.

The term “biphenyl group” as used herein refers to a phenyl group substituted with a phenyl group. The “biphenyl group” belongs to a substituted phenyl group having a C₆-C₆₀ aryl group as a substituent.

The term “terphenyl group” as used herein refers to a phenyl group substituted with a biphenyl group. The “terphenyl group” belongs to “a substituted phenyl group” having a “C₆-C₆₀ aryl group substituted with a C₆-C₆₀ aryl group” as a substituent.

The number of maximum carbon atoms in the definitions are illustrative only. For example, the number of maximum carbon atoms in the C₁-C₆₀ alkyl group of 60 may be exemplary and also be applied to the C₁-C₂₀ alkyl group. Other cases may also be the same.

The symbols * and *′ as used herein, unless defined otherwise, refer to a binding site to an adjacent atom in a corresponding formula.

Hereinafter, with reference to the Examples, the manufacture and evaluation of the display apparatus including the light-emitting apparatus will be described in detail.

### ≤Preparation of Green Quantum Dot Ink Composition≥

100 wt % of 1,6-hexanedilo diacrylate as a monomer, 100 wt % of Ag—In—Ga—S for green quantum dots based on 100 wt % of monomer, 10 wt % of scatterer TiO₂ based on 100 wt % of monomer, 0.1 wt % of initiator TPO based on 100 wt % of monomer, and 2 wt % of dispersant (—[CH₂—CH(COONa)—]ₘ/molecular weight in a range of 500 to 15,000) based on 100 wt % of monomer were mixed to prepare a green quantum dot ink composition.

### <Preparation of Red Quantum Dot Ink Composition>

100 wt % of 1,6-hexanedilo diacrylate as a monomer, 100 wt % of Ag—In—Ga—S for red quantum dots based on 100 wt % of monomer, 10 wt % of scatterer TiO₂ based on 100 wt % of monomer, 0.1 wt % of initiator TPO based on 100 wt % of monomer, and 2 wt % of dispersant (—[CH₂—CH(COONa)—]ₘ/molecular weight in a range of 500 to 15,000) based on 100 wt % of monomer were mixed to prepare a red quantum dot ink composition.

The Ag—In—Ga—S for green quantum dots and the Ag—In—Ga—S for red quantum dots have the same component but a different core size.

### <Preparation of Scatterer Ink Composition>

100 wt % of 1,6-hexanedilo diacrylate as a monomer, 20 wt % of scatterer TiO₂ based on 100 wt % of monomer, 0.1 wt % of initiator TPO based on 100 wt % of monomer, and 2 wt % of dispersant (—[CH₂—CH(COONa)—]ₘ/molecular weight in a range of 500 to 15,000) based on 100 wt % of monomer were mixed to prepare a scatterer ink composition.

### <Preparation of Organic Capping Layer Ink Composition>

An organic capping layer ink composition was prepared in the same manner as in Preparation of green quantum dot ink composition, except that the Ag—In—Ga—S for green quantum dots and the scatterer TiO₂ were omitted.

### Example 1

As shown in FIG. 1, first, as shown in FIG. 2A, the light-emitting device 120 was formed on the first substrate 110, and then was covered by a thin-film encapsulation layer 130. The emission layer included in the interlayer of the light-emitting device formed a blue emission layer as a common layer.

Next, as shown in FIG. 2B, the color filter layers 220R, 220G, and 220B were formed on a second substrate 210 at a position corresponding to the light-emitting device 120, and a partial region, in which the color filter layer 220R, the color filter layer 220G, and the color filter layer 220B overlapped to serve as a black matrix.

Next, as shown in FIG. 2C, a hollow silica material was prepared on the color filter layers 220R, 220G, and 220B to form a low-refractive-index layer 260 on the color filter layers 220R, 220G, and 220B. Then, on the low-refractive-index layer 260, the bank 240 was patterned on a region where the color filter layers 220R, 220G, and 220B overlapped such that the bank 240 may remain for each position between the color filter layers 220R, 220G, and 220B between each pixel.

Subsequently, as shown in FIG. 2D, the quantum dot layer 230R was formed on the red pixel by using the red quantum dot ink composition by an inkjet process, and the quantum dot layer 230G was formed on the green pixel by using the green quantum dot ink composition by an inkjet process. The scattering layer 230W was formed on the blue pixel by using the scatterer ink composition.

Subsequently, the organic capping layer 400 was formed by using the organic capping layer ink composition by an inkjet process on the quantum dot layer 230R, the quantum dot layer 230G, and the scattering layer 230W. More details of the process are as follows.

The organic capping layer 400 was formed again with inkjet on the quantum dot layer 230R, the quantum dot layer 230G, and the scattering layer 230W formed with inkjet, and then UV (390 nm) was irradiated for 50 seconds to cure the quantum dot layer 230R, the quantum dot layer 230G, the scattering Layer 230W, and the organic capping layer 400 simultaneously. Next, the quantum dot layer 230R, the quantum dot layer 230G, the scattering layer 230W, and the organic capping layer 400 were post-baked at 100 degrees in Celsius (° C.) for 10 minutes in an atmospheric atmosphere. The thickness of the organic capping layer 400 was 5 μm.

Next, silicon nitride was vapor-deposited to form the inorganic capping layer 270 having a thickness of 1,000 Å.

Next, as shown in FIG. 2E, the filling material 300 was applied between the first and second substrates 110 and 210 to bond the two substrates 110 and 210 together, thereby completing the manufacture of a display apparatus.

### Comparative Example 1

A display apparatus was manufactured in the same manner as in Example 1, except that the organic capping layer 400 was not formed on the quantum dot layer 230R, the quantum dot layer 230G, and the scattering layer 230W, UV (390 nm) was irradiated for 50 seconds to cure the quantum dot layer 230R, the quantum dot layer 230G, and the scattering layer 230W, the quantum dot layer 230R, the quantum dot layer 230G, and the scattering layer 230W were post-baked at 100° C. for 10 minutes in an atmospheric atmosphere, and silicon nitride was vapor-deposited in an atmospheric atmosphere to form the inorganic capping layer 270 having a thickness of 1,000 Å.

### Comparative Example 2

A display apparatus was manufactured in the same manner as in Example 1, except that the organic capping layer 400 was not formed on the quantum dot layer 230R, the quantum dot layer 230G, and the scattering layer 230W, UV (390 nm) was irradiated for 50 seconds to cure the quantum dot layer 230R, the quantum dot layer 230G, and the scattering layer 230W, the quantum dot layer 230R, the quantum dot layer 230G, and the scattering layer 230W were moved to the N₂ atmosphere line and post-baked at 100° C. for 10 minutes in an N₂ atmosphere, and silicon nitride was vapor-deposited in an N₂ atmosphere to form the inorganic capping layer 270 having a thickness of 1,000 Å.

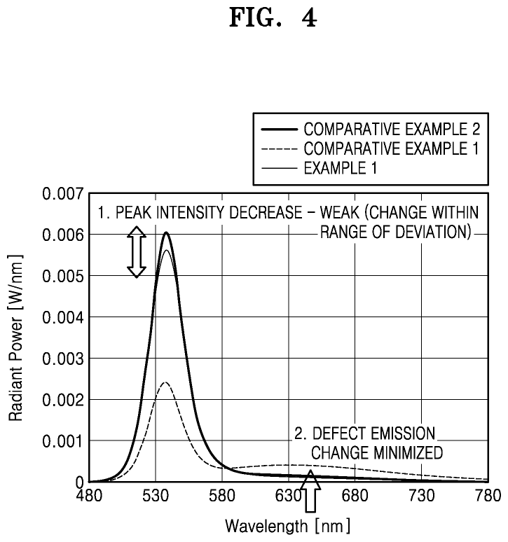

The light emission patterns of the display apparatuses of Example 1 and Comparative Examples 1 and 2 are shown in FIG. 4.

As shown in FIG. 4, the display apparatuses of Example 1 and Comparative Example 2 showed the same level of peaks.

However, the display apparatus of Comparative Example 1 showed a significant decrease in peak intensity and an increase in peak intensity at an unwanted long wavelength, as compared with the display apparatus of Example 1. This may result from a defect occurred in the quantum dot layer due to penetration of moisture and oxygen while forming the inorganic capping layer 270 under atmospheric conditions.

As apparent from the foregoing description, a quantum dot layer of a display apparatus may be protected from penetration of moisture and oxygen, and thus, for example, an N₂ atmosphere inline process is not required.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a first substrate on which a light-emitting device is located; and
a light controller on the first substrate and corresponding to the light-emitting device,
wherein the light controller comprises:
an organic capping layer; a quantum dot layer and/or a scattering layer; and a color filter layer, and
wherein the organic capping layer is adjacent to the quantum dot layer and/or the scattering layer.

2. The display apparatus of claim 1, wherein a monomer used in forming the organic capping layer and a monomer used in forming the quantum dot layer and/or the scattering layer are monomers of a same series.

3. The display apparatus of claim 1, wherein a monomer used in forming the organic capping layer is an acrylic monomer.

4. The display apparatus of claim 1, wherein a monomer used in forming the quantum dot layer and/or the scattering layer is an acrylic monomer.

5. The display apparatus of claim 1, wherein the organic capping layer is located between: the quantum dot layer and/or the scattering layer; and the color filter layer.

6. The display apparatus of claim 1, wherein the quantum dot layer and/or the scattering layer, and the organic capping layer are each formed by an inkjet printer.

7. The display apparatus of claim 1, wherein the quantum dot layer and/or the scattering layer, and the organic capping layer are each cured simultaneously.

8. The display apparatus of claim 1, wherein a monomer used in forming the organic capping layer comprises hexamethylene diacrylate, tetraethylene glycol diacrylate, dipropylene glycol diacrylate, tripropylene glycol diacrylate, or any combination thereof.

9. The display apparatus of claim 1, wherein a thickness of the organic capping layer is in a range of about 0.1 micrometers (μm) to about 10 μm.

10. The display apparatus of claim 1, wherein the light controller further comprises a low-refractive-index layer,
wherein the low-refractive-index layer is located between: the quantum dot layer and/or the scattering layer; and the color filter layer.

11. The display apparatus of claim 1, wherein the quantum dot layer comprises a quantum dot,
wherein the quantum dot comprises: a group II-VI semiconductor compound; a group III-V semiconductor compound; a group III-VI semiconductor compound; a group I-III-VI semiconductor compound; a group IV-VI semiconductor compound; a group IV element or compound; or any combination thereof.

12. The display apparatus of claim 11, wherein the group II-VI semiconductor compound comprises CdS, CdSe, CdTe, ZnS, ZnSe, ZnTe, ZnO, HgS, HgSe, HgTe, MgSe, MgS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, CdZnSeS, CdZnSeTe, CdZnSTe, CdHgSeS, CdHgSeTe, CdHgSTe, HgZnSeS, HgZnSeTe, HgZnSTe, or any combination thereof.

13. The display apparatus of claim 11, wherein the group III-V semiconductor compound comprises GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or any combination thereof.

14. The display apparatus of claim 11, wherein the group semiconductor compound comprises AgInS, AgInS₂, CuInS, CuInS₂, CuGaO₂, AgGaO₂, AgAlO₂, AgInGaS, or any combination thereof.

15. The display apparatus of claim 1, further comprising a second substrate facing the first substrate,
wherein the light controller is located between the first substrate and the second substrate, and the organic capping layer is located between the light-emitting device and the quantum dot layer.

16. The light-emitting device of claim 15, wherein the display apparatus further comprises an inorganic capping layer,
wherein the inorganic capping layer is located between the organic capping layer and the light-emitting device, and the inorganic capping layer is adjacent to the organic capping layer.

17. The display apparatus of claim 1, wherein the light-emitting device is configured to emit blue light, red light, or light consisting of a combination thereof.

18. The display apparatus of claim 1, wherein the light-emitting device is configured to emit light including light of a wavelength in a range of about 380 nanometers (nm) to about 780 nm, and the quantum dot layer is configured to change color of the light to one of red light and green light.

19. A light controller comprises:
a bank;
a quantum dot layer and/or a scattering layer, in the bank;
an organic capping layer in the bank and adjacent to the quantum dot layer and/or the scattering layer; and
an inorganic capping layer covering the bank and the organic capping layer.

20. The light controller of claim 19, further comprising a color filter layer.
